(19) United States
(12) Patent Application Publication
(10) Pub. No.: US 2026/0026036 A1
(43) Pub. Date: Jan. 22, 2026

(54) SEMICONDUCTOR DEVICE

(71) Applicant: ROHM CO., LTD., Kyoto (JP)

(72) Inventor: Shusaku FUJIE, Kyoto (JP)

(73) Assignee: ROHM CO., LTD., Kyoto (JP)

(21) Appl. No.: 19/262,877

(22) Filed: Jul. 8, 2025

(30) Foreign Application Priority Data
Jul. 19, 2024 (JP) 2024-116069

(51) Int. Cl. H10D 30/65; H10D 64/00

(52) U.S. Cl. CPC H10D 30/655; H10D 64/112

(57) ABSTRACT

A semiconductor device includes a semiconductor substrate, a semiconductor layer, a high voltage element region and a low voltage element region, and an isolation structure formed on an insulating film on the semiconductor layer. The isolation structure surrounds the high voltage element region to isolate the high voltage element region from the low voltage element region. An embedded layer is interposed between the semiconductor substrate and the semiconductor layer. In a plan view, the high voltage element region includes outer edges having linear sides and corners. The embedded layer has an overlap section where the embedded layer overlaps the high voltage element region, and outer edge sections that protrude from the outer edges. The outer edge sections include extending sections corresponding to the sides and curved sections corresponding to the corners. A width of each of the extending sections is greater than a width of each of the curved sections.

### CROSS REFERENCE TO RELATED APPLICATION

This application is based upon and claims the benefit of priority of the prior Japanese Patent Application No. 2024-116069, filed on Jul. 19, 2024, the entire contents of which are incorporated herein by reference.

### Technical Field

The present disclosure relates to a semiconductor device.

### Background Art

Japanese Patent Application Laid-Open Publication No. 2018-011089 discloses a semiconductor device including a high voltage element region, a low voltage element region, an element isolation well that isolates the foregoing elements, and an embedded layer.

### BRIEF DESCRIPTION OF THE DRAWINGS

FIG. 1 is a plan view of a semiconductor device according to Embodiment 1.

FIG. 2 is an expanded view of a device region I shown in FIG. 1.

FIG. 3 is a cross-sectional view along the line III-III in FIG. 2.

FIG. 4 is a schematic view of a relationship between an embedded layer and a high voltage element region according to Embodiment 1.

FIG. 5 is an enlarged view of a region V shown in FIG. 4.

FIG. 6 is a schematic view of a relationship between an embedded layer and a high voltage element region according to a comparison example.

FIG. 7 is an enlarged view of a region VII shown in FIG. 6.

FIG. 8A is a cross-sectional view along the line VIIIa-VIIIa in FIG. 5. FIG. 8B is a cross-sectional view along the line VIIIb-VIIIb in FIG. 5.

FIG. 9A is a cross-sectional view along the line IXa-IXa in FIG. 7. FIG. 9B is a cross-sectional view along the line IXb-IXb in FIG. 7.

FIG. 10 is a graph comparing the impurity concentration along the line L1 of the configuration shown in FIGS. 8A and 8B, and the impurity concentration along the line L2 of the configuration shown in FIGS. 9A and 9B.

FIG. 11 is a photograph showing the result of a voltage breakdown experiment.

FIG. 12 is an expanded view of the configuration of a main section of a semiconductor device according to Embodiment 2.

FIG. 13 is an expanded view of the configuration of a main section of a semiconductor device according to Embodiment 3.

### DETAILED DESCRIPTION OF EMBODIMENTS

Below, various exemplary embodiments will be described in detail with reference to the drawings. The same or corresponding components in the drawings are assigned the same reference characters and redundant explanations thereof will be omitted.

### Embodiment 1

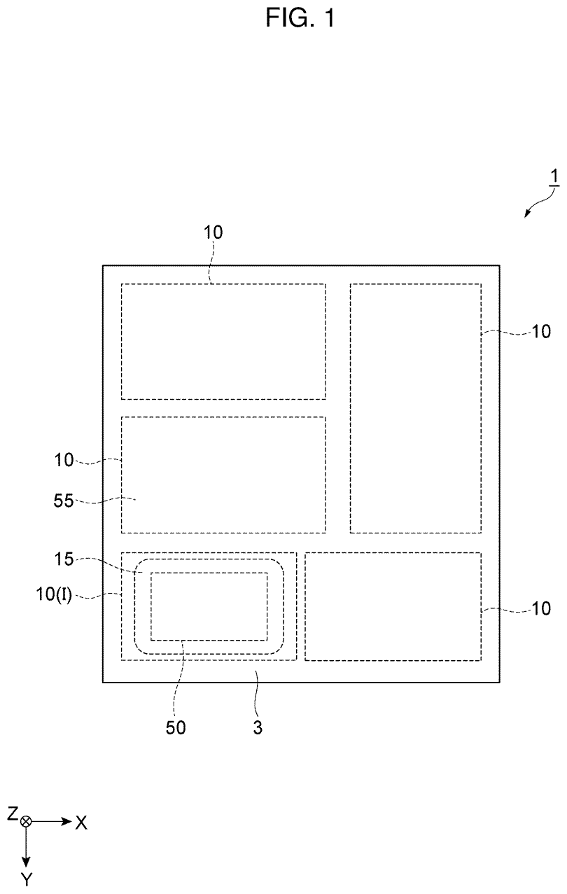

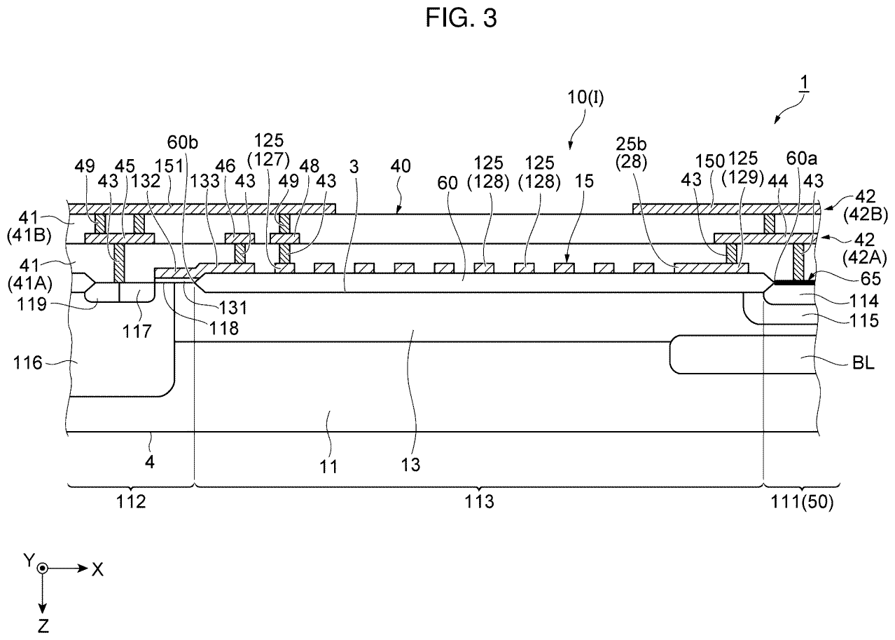

FIG. 1 is a plan view of a semiconductor device according to Embodiment 1. A semiconductor device 1 according to Embodiment 1 is a semiconductor chip having a rectangular cuboid shape. The thickness direction of the semiconductor device 1 is designated as the Z axis direction, a direction orthogonal to the Z axis is designated as the X axis direction, and the direction orthogonal to both the Z axis and the X axis is designated as the Y axis direction. The semiconductor device 1 has a first main surface 3 and a second main surface 4 that face opposite directions to each other in the Z axis direction (see FIG. 3). In Embodiment 1, the first main surface 3 is the front surface and the second main surface 4 is the rear surface. The direction from the first main surface 3 towards the second main surface 4 is designated as the positive Z axis direction, and the direction from the second main surface 4 towards the first main surface 3 is designated as the negative Z axis direction. The semiconductor device 1 has four side faces that connect the first main surface 3 and the second main surface 4.

The first main surface 3 and the second main surface 4 are both perpendicular to the Z axis. The planar shape (plan view shape) of the first main surface 3 as seen from the normal line direction (Z axis direction) of the first main surface 3 is rectangular (quadrilateral). The plan view shape of the second main surface 4 is rectangular (quadrilateral). One pair of opposing side faces extend along the XZ plane constituted of the X axis and the Z axis. Another pair of opposing side faces extend along the YZ plane constituted of the Y axis and the Z axis. Among the side faces, adjacent side faces are perpendicular to each other, but can alternatively intersect at a non-right angle.

The semiconductor device 1 includes a plurality of device regions 10 provided on the first main surface 3. A gap is provided between each device region 10 and each side face of the semiconductor device 1. These device regions 10 are sections used for ease of explanation, and the actual device regions 10 do not have physical boundaries.

Various devices are formed in each of the device regions 10. In Embodiment 1, at least one device region 10 (device region I) includes a high voltage element region 50 and an isolation structure 15 provided to the semiconductor layer 13. In the high voltage element region 50, at least one high voltage clement that operates at a high reference voltage is disposed. The high voltage clement may be a FET such as a lateral double-diffused MISFET (LDMISFET). In order to operate the high voltage clement, a high voltage of 100V or higher is applied to the high voltage clement region 50, for example. If the high voltage element is an LDMISFET, then a drain voltage of 800V or higher can be applied when the high voltage element is in the OFF state, for example.

At least one device region 10 other than the device region I includes a low voltage clement region 55 in which a low voltage element is disposed, and is arranged so as to be adjacent to the device region I. In order to operate the low voltage element, a voltage of 0V to 100V is applied to the low voltage element region 55, for example.

The isolation structure 15 is formed on the first main surface 3, and surrounds the high voltage element region 50 so as to isolate the high voltage element region 50 from the low voltage element region 55. The isolation structure 15 overall has a loop shape in a plan view.

The semiconductor material constituting the semiconductor device 1 of Embodiment 1 is silicon (Si). The semiconductor material constituting the semiconductor device 1 can also be a compound semiconductor. Such compound semiconductors include III-V compound semiconductors, IV-IV compound semiconductors, or mixed crystal semiconductors including the foregoing semiconductors. Ga-containing semiconductors such as GaAs and GaN can be used as the III-V compound semiconductors. Silicon-containing semiconductors such as silicon carbide (SiC) and silicon germanium (SiGe) can be used as the IV-IV compound semiconductors.

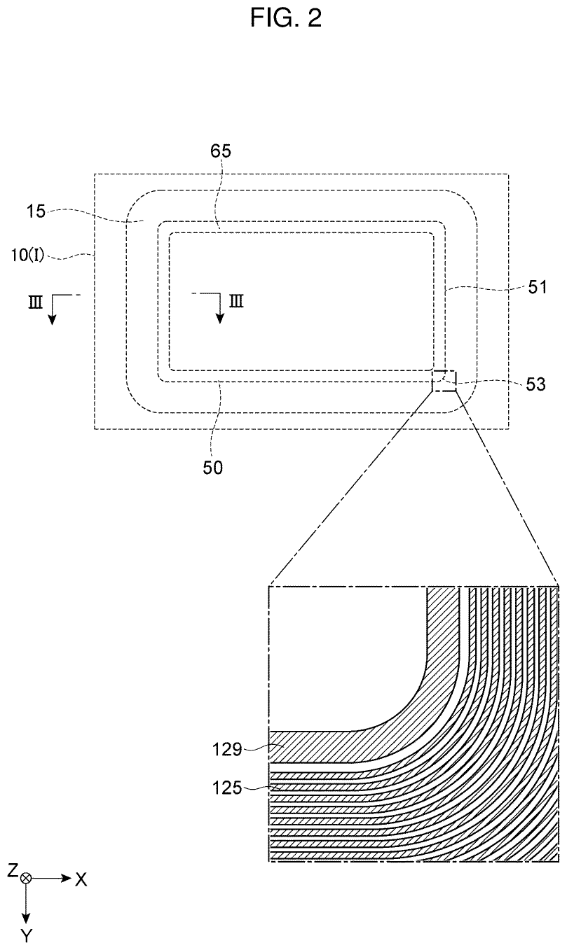

FIG. 2 is an expanded view of a device region I shown in FIG. 1. The device region I is an example of the device region 10 including the high voltage element region 50 and the isolation structure 15.

As shown in FIG. 2, the isolation structure 15 includes a field electrode 125 arranged in a spiral shape. The pattern on the lower right of FIG. 2 shows a detailed view of the field electrode 125 in the vicinity of one corner 53 of the high voltage element region 50. The isolation structure 15 is not limited to a spiral field electrode as long as the effect of isolation of the high voltage element region 50 from the low voltage element region 55 (see FIG. 1) is exhibited.

The high voltage element region 50 has an active region 65. The active region 65 has a rectangular loop shape corresponding to the shape (rectangle) of the high voltage element region 50 in a plan view, and surrounds the section where the high voltage element is disposed. Outer edges 51 of the high voltage element region 50 are constituted of outer edges of the active region 65.

FIG. 3 is a cross-sectional view along the line III-III in FIG. 2, and shows a partial cross-sectional configuration of the device region I. As shown in FIG. 3, the semiconductor device 1 includes a semiconductor substrate 11, a semiconductor layer 13, an embedded layer BL, an insulating film 60, and an isolation structure 15.

The semiconductor substrate 11 has the second main surface 4 of the semiconductor device 1. The semiconductor layer 13 is provided on the main surface opposite to the second main surface 4 of the semiconductor substrate 11. The semiconductor layer 13 has the first main surface 3 of the semiconductor device 1. The high voltage element region 50 and the low voltage element region 55 (see FIG. 1) are provided to the semiconductor layer 13. The embedded layer BL is interposed between the semiconductor substrate 11 and the semiconductor layer 13. The insulating film 60 is formed on the first main surface 3 of the semiconductor layer 13. The isolation structure 15 is formed over the first main surface 3 of the semiconductor layer 13, with the insulating film 60 interposed therebetween.

The semiconductor layer 13 is made of an n-type (first conductivity type)

semiconductor. The semiconductor substrate 11 is made of a p-type (second conductivity type) semiconductor. In Embodiment 1, the first conductivity type is the n type and the second conductivity type is the p type, but the conductivity types may be the opposite thereto.

The device region I includes a first potential region 111, a second potential region 112, and a drift region 113. The first potential region 111 is a region to which a first potential is applied, and is positioned at the center of the device region I. The second potential region 112 is a region to which a second potential differing from the first potential is applied, and is separated from the first potential region 111 in a cross-sectional view. The second potential region 112 surrounds the first potential region 111 and the drift region 113 in a plan view. The first potential region 111 is a high potential region to which a high potential (first potential) is applied, and the second potential region 112 is a low potential region to which a low potential (second potential) less than the high potential is applied, for example. The drift region 113 is positioned between the first potential region 111 and the second potential region 112.

In the semiconductor device 1, the first potential region 111 in the device region I is the high voltage clement region 50. The second potential region 112 in the device region I may be connected to the low voltage element region 55 in device regions 10 other than the device region I.

The first potential region 111 includes a drain region 114 and a well region 115. The drain region 114 and the well region 115 are provided towards the top of the semiconductor layer 13. The well region 115 surrounds the drain region 114 in a plan view, and is in contact with the drain region 114. In a plan view, the drain region 114 is separated from the inner and outer edges of the well region 115. In other words, in a plan view, the drain region 114 is positioned to the inside of the outer edge of the well region 115, and is positioned to the outside of the inner edge of the well region 115. The drain region 114 is positioned inside the well region 115 in a plan view. In a plan view, the center of the drain region 114 in the width direction matches the center of the well region 115 in the width direction. The drain region 114 constitutes a portion of the first main surface 3.

The n-type impurity concentration of the well region 115 is higher than the n-type impurity concentration of the semiconductor layer 13. Also, the n-type impurity concentration of the drain region 114 is higher than the n-type impurity concentration of the well region 115. The n-type impurity concentration of the well region 115 may be 1.0×10¹⁵cm⁻³ to 1.0×10¹⁸cm⁻³, inclusive, for example. The n-type impurity concentration of the drain region 114 may be 1.0×10¹⁸ cm⁻³ to 1.0×10²¹cm⁻³, inclusive, for example.

In Embodiment 1, the drain region 114 and the well region 115 have a rectangular loop shape in a plan view, but the shape is not limited thereto. As long as the drain region 114 and the well region 115 have a loop shape that traces the outer edges 51 of the high voltage element region 50, any shape may be used. If the high voltage clement region 50 has a polygonal shape other than a rectangle in a plan view (e.g., triangular or L-shaped), then the drain region 114 and the well region 115 may have a polygonal loop shape corresponding to the shape of the high voltage clement region 50.

In Embodiment 1, the n-type impurity concentration of the embedded layer BL is higher than the n-type impurity concentration of the semiconductor layer 13. The n-type impurity concentration of the embedded layer BL may be higher than the n-type impurity concentration of the well region 115. The embedded layer BL is provided at a position separated from the well region 115 in the Z axis direction. Thus, a portion of the semiconductor layer 13 is positioned between the embedded layer BL and the well region 115 in the Z axis direction. The embedded layer BL mitigates leakage current from the high voltage element in the depth direction of the semiconductor substrate.

In a plan view, the embedded layer BL is provided so as to overlap the entire high voltage clement region 50. In a plan view, the embedded layer BL is provided up to the outside of the outer edge of the well region 115, for example. The embedded layer BL has a substantially rectangular shape in a plan view, but the shape is not limited thereto. As long as the embedded layer BL has a shape overlapping the entire high voltage clement region 50 in a plan view, if the high voltage element region 50 has a polygonal shape other than a rectangle in a plan view (e.g., triangular or L-shaped), then the embedded layer BL may have a polygonal shape corresponding to the shape of the high voltage element region 50. The area of the embedded layer BL in a plan view may be greater than the area of the well region 115.

The second potential region 112 includes a p-type body region 116 separated from the well region 115 in a plan view. The body region 116 extends along the edge of the semiconductor layer 13, for example. The body region 116 specifically has a rectangular loop shape surrounding the isolation structure 15 in a plan view. The body region 116 extends from the first main surface 3, through the semiconductor layer 13, and to the semiconductor substrate 11 in the Z axis direction. Thus, the body region 116 is electrically connected to the semiconductor substrate 11, and is fixed to the potential of the semiconductor substrate 11 (e.g., back-gate potential). The body region 116 may be provided to both the semiconductor substrate 11 and the semiconductor layer 13. The p-type impurity concentration of the body region 116 may be 1.0×10¹⁵cm⁻³ to 1.0×10¹⁸cm⁻³, inclusive, for example.

The semiconductor device 1 includes a source region 117 provided to the body region 116. The source region 117 is an n-type region and is fixed to source potential. The source potential is applied to the source region 117 from the outside. In the semiconductor layer 13, a p-type channel region 118 in the above-mentioned FET structure is formed between the source region 117 and the drift region 113 in the X axis direction. Thus, a current path extending in the X axis direction is formed in the drift region 113 between the source region 117 and the drift region 113 in the X axis direction. The source potential corresponds to the second potential. The n-type impurity concentration of the source region 117 is higher than the n-type impurity concentration of the well region 115. The n-type impurity concentration of the source region 117 may be equal to the n-type impurity concentration of the drain region 114. The n-type impurity concentration of the source region 117 may be 1.0×10¹⁸cm⁻³ to 1.0×10²¹cm⁻³, inclusive, for example. In the channel region 118 the current path between the drain region 114 and the source region 117 is controlled to be conductive or non-conductive.

The source region 117 is positioned inside of the body region 116 and to the inside of the outer edge of the body region 116 in a plan view. The source region 117 constitutes a portion of the first main surface 3, or in other words, a portion of the surface layer of the body region 116.

The second potential region 112 includes a contact region 119 provided to the body region 116. In Embodiment 1, the semiconductor device 1 includes the contact region 119. The contact region 119 is a p-type region. The p-type impurity concentration of the contact region 119 may be higher than the p-type impurity concentration of the body region 116. The p-type impurity concentration of the contact region 119 may be 1.0×10¹⁸cm⁻³ to 1.0×10²¹cm⁻³, inclusive, for example.

The contact region 119 is positioned inside of the body region 116 and to the inside of the outer edge of the body region 116 in a plan view. The contact region 119 is positioned closer to the outer edge of the body region 116 than the source region 117. The contact region 119 constitutes a portion of the first main surface 3, or in other words, a portion of the surface layer of the body region 116.

The contact region 119 is positioned between the corresponding source region 117 and the outer edge of the body region 116 in a plan view. The contact region 119 is adjacent to the source region 117 in a plan view. Thus, at the surface layer of the body region 116, the source region 117 fixed to source potential and the contact region 119 fixed to a potential differing from the source potential are both present.

The semiconductor device 1 includes the n-type drift region 113 present between the drain region 114 and the source region 117, and on the surface layer of the semiconductor layer 13. The drift region 113 has a rectangular loop shape surrounding the drain region 114 in a plan view, for example. The width of the drift region 113 corresponds to the distance between the first potential region 111 and the second potential region 112.

The insulating film 60 selectively covers the first main surface 3 in the device region I. The insulating film 60 includes a silicon oxide. The insulating film 60 includes a local oxidation of silicon film (LOCOS film) made through selective oxidation of the first main surface 3, an embedded oxide film (shallow trench isolation (STI)) that embeds a shallow groove provided in the first main surface 3, and the like. The insulating film 60 may have a single-layer structure or a multilayer structure.

The insulating film 60 is positioned above the drift region 113 in the Z axis direction, and covers a region between the drain region 114 and the source region 117 at the first main surface 3. The insulating film 60 has a rectangular loop shape surrounding the drain region 114 in a plan view, for example, and includes an inner edge 60a and an outer edge 60b. In Embodiment 1, the inner edge 60a of the insulating film 60 overlaps the outer edge of the drain region 114 in the Z axis direction, but need not necessarily overlap the drain region 114. The outer edge 60b of the insulating film 60 is positioned to the inside of the inner edge of the body region 116 in a plan view.

The drain region 114, the body region 116, the source region 117, the contact region 119, and the drift region 113 have exposed surfaces that are exposed through the insulating film 60. The exposed surface of the drain region 114 constitutes the active region 65. The drain region 114 is a portion of the first main surface 3, and thus, the first main surface 3 can be said to have an active region 65 with a loop shape exposed through the insulating film 60.

The semiconductor device 1 includes the field electrode 125 positioned on the insulating film 60 in the device region I. The field electrode 125 has the function of mitigating a disordered electric field in the semiconductor layer 13 or the like, the function of mitigating localized concentration of the electric field, the function of monitoring the high voltage drain-gate voltage Vdg, and the like. The field electrode 125 is a high resistance film connected to the first potential region 111 and the second potential region 112.

The field electrode 125 overlaps the drift region 113 in the Z axis direction. In Embodiment 1, the field electrode 125 does not overlap the channel region 118 in the Z axis direction. The field electrode 125 contains polysilicon, for example. The field electrode 125 is electrically connected to at least the drain region 114. In Embodiment 1, the field electrode 125 forms a potential gradient that gradually changes from the first potential region 111 to the second potential region 112. By providing such a field electrode 125, an uneven distribution of the electric field in the drift region 113 is mitigated. The thickness of the field electrode 125 is 50 nm to 100 nm, inclusive, for example.

The field electrode 125 surrounds the first potential region 111 a plurality of times in a plan view, for example. In Embodiment 1, the field electrode 125 has a spiral shape that surrounds the first potential region 111 in a plan view.

The field electrode 125 has a first end 129 positioned in the vicinity of the drain region 114, a second end 127 positioned in the vicinity of the body region 116, and a spiral section 128 that extends between the first end and the second end.

The first end 129 of the field electrode 125 is a connecting section that is electrically connected to the drain region 114. The first end 129 is a portion (innermost circumferential section) of the field electrode 125 positioned furthest to the inside. The potential of the first end 129 is fixed at the first potential. The first end 129 may overlap the well region 115 in the Z axis direction.

The second end 127 of the field electrode 125 is a portion (outermost circumferential section) of the field electrode 125 positioned furthest to the outside. The potential applied to the second end 127 is the second potential or a potential similar thereto. The second end 127 may overlap the drift region 113 in the Z axis direction.

The spiral section 128 of the field electrode 125 is a section connected to the first end 129 and the second end 127 described above. The spiral section 128 is wound in a rectangular spiral from the first end 129 to the second end 127 so as to surround the first potential region 111 in a plan view. The spiral section 128 overlaps the drift region 113 in the Z axis direction. A portion of the spiral section 128 can overlap the well region 115.

The field electrode 125 forms a potential gradient in a spiraling direction from the first end 129 towards the second end 127. The field electrode 125 forms a potential gradient that gradually decreases according to the winding pitch of the spiral section from the first potential region 111 to the second potential region 112 in a direction orthogonal to the spiraling direction. The field electrode 125 thins the electric field in the drift region 113 and mitigates uneven distribution of the electric field in the drift region 113.

The field electrode 125 may have a line width of 0.5 μm to 5 μm, inclusive. The line width is defined as the width in the direction perpendicular to the extension direction of the field electrode 125 (i.e., the spiraling direction). The first end 129 may be formed wider than the second end 127 and the spiral section 128. The field electrode 125 may have a resistance of 10MΩ to 100MΩ, inclusive.

The pitch of the field electrode 125 may be 1 μm to 10 μm, inclusive. The pitch of the field electrode 125 is defined by the distance between adjacent line sections (i.e., the winding pitch of the spiral section). The number of times the field electrode 125 is wound is five to 100, inclusive, for example. The number of times the field electrode 125 is wound may be 75 or less or may be 50 or less.

The semiconductor device 1 includes a gate insulating film 131 that is in contact with the semiconductor layer 13 and is positioned on the channel region 118. A portion of the gate insulating film 131 overlaps the insulating film 60. The thickness of the gate insulating film 131 is less than the thickness of the insulating film 60, and is 10 nm to 200 nm, inclusive, for example. The gate insulating film 131 has a single-layer structure or a multilayer structure, and includes a silicon oxide film, for example. In Embodiment 1, the gate insulating film 131 has a rectangular loop shape that surrounds the insulating film 60 in a plan view. The gate insulating film 131 covers a portion of the drift region 113 and a portion of the body region 116.

The semiconductor device 1 includes a gate electrode 132 positioned on the gate insulating film 131. The gate electrode 132 contains a metal film, an alloy film, or conductive polysilicon, for example. If the gate electrode 132 contains conductive polysilicon, then the conductive polysilicon includes an n-type region and/or a p-type region. The gate electrode 132 overlaps not only the channel region 118 but also the drift region 113 in the Z axis direction. The gate electrode 132 has a rectangular loop shape that extends along the channel region 118 in a plan view, but the shape is not limited thereto. The gate electrode 132 has a lead-out section 133 that is lead out from above the gate insulating film 131 to above the insulating film 60. The lead-out section 133 has a rectangular loop shape that surrounds the field electrode 125 in a plan view, and is positioned on the drift region 113. Also, the entire gate electrode 132 is positioned outside of the field electrode 125 in a plan view.

The semiconductor device 1 includes an insulating layer 40 that covers the plurality of device regions 10 on the first main surface 3. The insulating layer 40 has a layered structure including a plurality of interlayer insulating films 41 that are stacked. Any number of the plurality of interlayer insulating films 41 can be provided, and there is no specific limitation to the number. The insulating layer 40 may include three or more interlayer insulating films 41. In FIG. 3, a first interlayer insulating film 41A and a second interlayer insulating film 41B among the plurality of interlayer insulating films 41 are shown.

The first interlayer insulating film 41A and the second interlayer insulating film 41B are stacked in the stated order in the Z axis direction. The first interlayer insulating film 41A covers at least the first main surface 3, the insulating film 60, the gate insulating film 131, and the gate electrode 132. The second interlayer insulating film 41B covers the first interlayer insulating film 41A. The thickness of the first interlayer insulating film 41A and the thickness of the second interlayer insulating film 41B are determined according to the expected function of the field electrode 125, the thickness of the insulating film 60, and the like, for example. The first interlayer insulating film 41A and the second interlayer insulating film 41B include a silicon oxide film and/or a silicon nitride film. The first interlayer insulating film 41A and the second interlayer insulating film 41B may each have a single-layer structure or a multilayer structure.

A plurality of wiring films 42 are provided in the insulating layer 40. In Embodiment 1, the plurality of interlayer insulating films 41 and the plurality of wiring films 42 are alternately stacked. Thus, a multilayer wiring structure is provided on the semiconductor layer 13. Any number of the wiring films 42 can be layered, and there is no specific limitation to the number. In FIG. 3, among the plurality of wiring films 42, a first wiring film 42A positioned on the first interlayer insulating film 41A and a second wiring film 42B positioned on the second interlayer insulating film 41B are shown. Each wiring film 42 includes at least one of an Al film, a Cu film, an AlSiCu alloy film, an AlSi alloy film, and an AlCu alloy film, for example. Thus, the first wiring film 42A and the second wiring film 42B may each have a single-layer structure or a multilayer structure.

A plurality of first vias 43 and a plurality of second vias 49 are provided in the insulating layer 40. Each of the plurality of first vias 43 is a conductive unit that electrically connects the first wiring film 42A to conductive portions such as the first potential region 111, the second potential region 112, and the field electrode 125, which are positioned below the first interlayer insulating film 41A, and penetrates the first interlayer insulating film 41A. Each of the plurality of second vias 49 is a conductive unit that electrically connects the second wiring film 42B to conductive portions such as the first wiring film 42A positioned below the second interlayer insulating film 41B, for example, and penetrates the second interlayer insulating film 41B. The plurality of first vias 43 and the plurality of second vias 49 are tungsten plugs, for example.

The first wiring film 42A includes a first drain wiring line 44, a first source wiring line 45, a first gate wiring line 46, and a field wiring line 48, for example. The first drain wiring line 44 is electrically connected to the drain region 114 and the first end 129 of the field electrode 125 through one or more first vias 43. The first source wiring line 45 is electrically connected to the source region 117 through one or more first vias 43. The first gate wiring line 46 is electrically connected to the gate electrode 132 through one or more first vias 43. The field wiring line 48 is electrically connected to the second end 127 of the field electrode 125 through one or more first vias 43. The field wiring line 48 may be a portion of the first source wiring line 45.

A plurality of the second wiring films 42B include a second drain wiring line 150, a second source wiring line 151 and a second gate wiring line (not shown), for example. The second drain wiring line 150 is electrically connected to the first drain wiring line 44 through the plurality of second vias 49. The second drain wiring line 150 overlaps the drain region 114. The second drain wiring line 150 may overlap the entire drain region 114. The second drain wiring line 150 may overlap the first end 129 of the field electrode 125. The second source wiring line 151 is electrically connected to the first source wiring line 45 and the field wiring line 48 through the plurality of second vias 49. The second source wiring line 151 has a loop shape that extends along the body region 116 in a plan view. The second source wiring line 151 may overlap the gate electrode 132 and the field wiring line 48. The second source wiring line 151 may overlap the entire body region 116, the entire gate electrode 132, and the entire field wiring line 48.

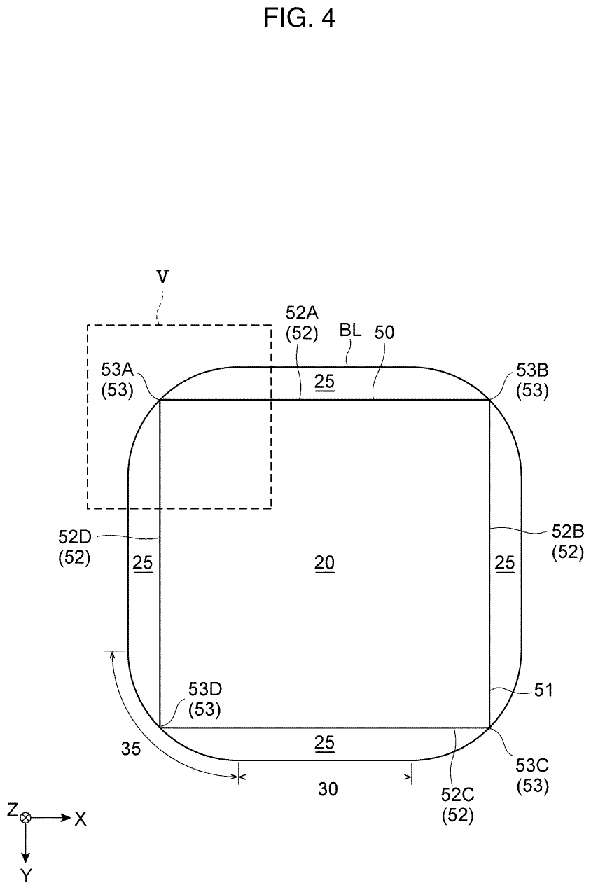

FIG. 4 is a schematic view of a relationship between the embedded layer and the high voltage element region according to Embodiment 1. In FIG. 4, only the embedded layer BL and the high voltage element region 50 are shown in a plan view, and other portions are omitted.

As shown in FIG. 4, in a plan view, the high voltage element region 50 has a substantially rectangular shape. In a plan view, the high voltage element region 50 has a square shape as one example, but may have a rectangular shape as shown in FIG. 1. The high voltage element region 50 includes the outer edges 51. The outer edges 51 include linear sides 52 and corners 53. The sides 52 include four sides 52A to 52D. The corners 53 include four corners 53A to 53D. The embedded layer BL is positioned below the high voltage element region 50 in the Z axis direction. In a plan view, the embedded layer BL has a substantially rectangular shape. The embedded layer BL is greater in area than the high voltage element region 50.

In the plan view of FIG. 4, the embedded layer BL has an overlap section 20 where the embedded layer BL overlaps the high voltage element region 50, and outer edges 25 where the embedded layer BL protrudes outside of the outer edges 51 of the high voltage element region 50. The outer edges 25 of the embedded layer BL include extending sections 30 corresponding to the sides 52 of the high voltage element region 50 and curved sections 35 corresponding to the corners 53 of the high voltage element region 50. The number of extending sections 30 is equal to the number of sides 52, which is four in Embodiment 1. The number of curved sections 35 is equal to the number of corners 53, which is four in Embodiment 1.

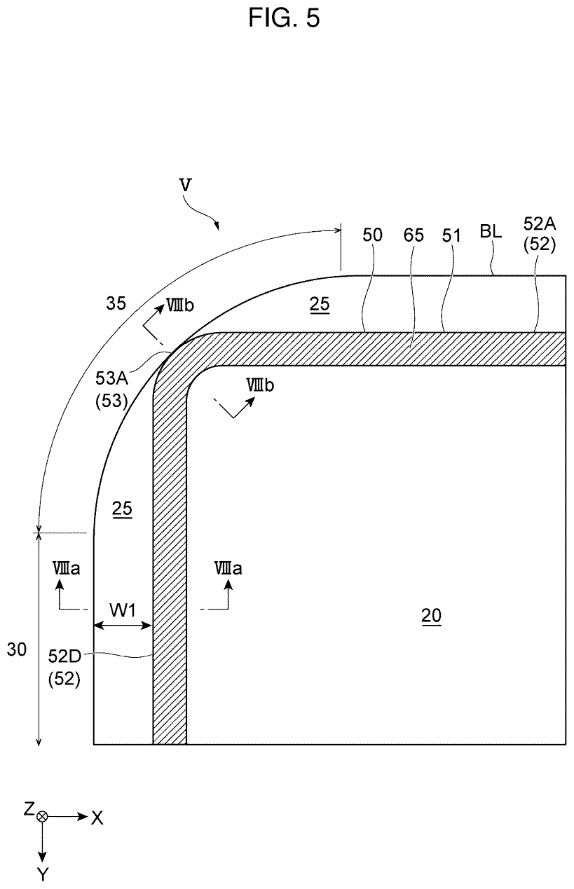

Additionally, the configuration of the vicinity of each of the curved sections 35 corresponding to the corners 53A will be described with reference to FIG. 5. FIG. 5 is an enlarged view of a region V shown in FIG. 4. FIG. 5 shows not only the embedded layer BL and the high voltage element region 50, but also the active region 65. As shown in FIGS. 4 and 5, the curvature radius of the curved section 35 is greater than the curvature radius of the corner 53. Thus, in a plan view, at the curved section 35, the outer edge of the embedded layer BL is set back towards the outer edge 51 of the high voltage element region 50 as compared to the extending section 30. As a result, the outer edge of the embedded layer BL approaches the outer edge 51 of the high voltage element region 50 in the curved section 35, and therefore, a width W1 of the extending section 30 is greater than a width W2 (not shown) of the curved section 35.

The width W1 is the distance by which the embedded layer BL protrudes out from the side 52 of the high voltage element region 50 at the extending section 30. The width W1 may be a constant value throughout the extension direction of the extending section 30 or may be variable. The width W1 is the maximum width of the extending section 30, for example. The width W1 may be the width of the outer edge 25 at the center of the side 52. In this case, the width W1 is the distance that the embedded layer BL protrudes from the center of the side 52 in the direction perpendicular to the side 52.

The width W2 is the distance by which the embedded layer BL protrudes out from the corner 53 of the high voltage element region 50 at the curved section 35. The width W2 is the width of the outer edge 25 at the vertex of the corner 53, for example. That is, the width W2 is the distance that the embedded layer BL protrudes from the vertex of the corner 53 in the direction perpendicular to the tangent line of the corner 53. The width W2 may be the distance between the vertex of the curved section 35 and the vertex of the corner 53.

In FIGS. 4 and 5, an example is shown in which the vertex of the curved section 35 overlaps the vertex of the corner 53. That is, the distance (width W2) between the vertex of the curved section 35 and the vertex of the corner 53 is zero.

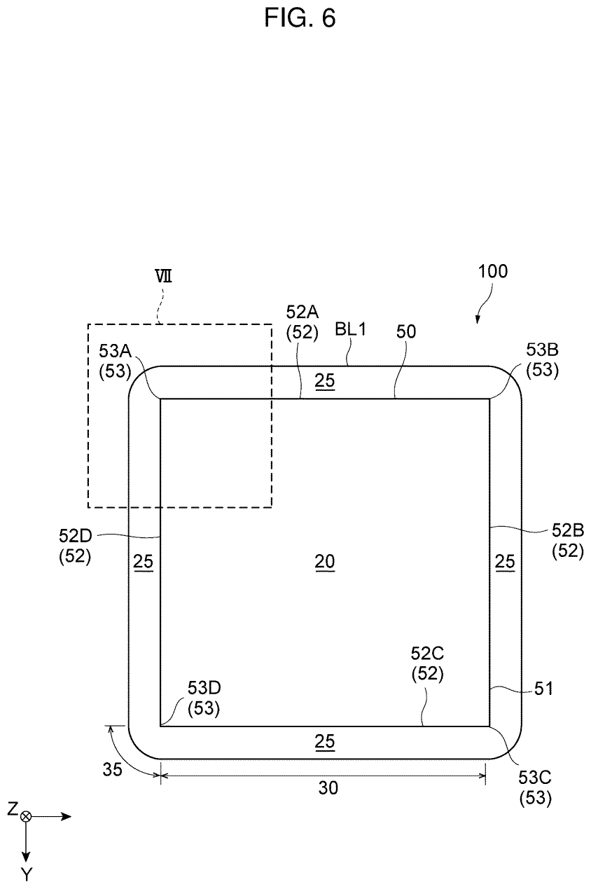

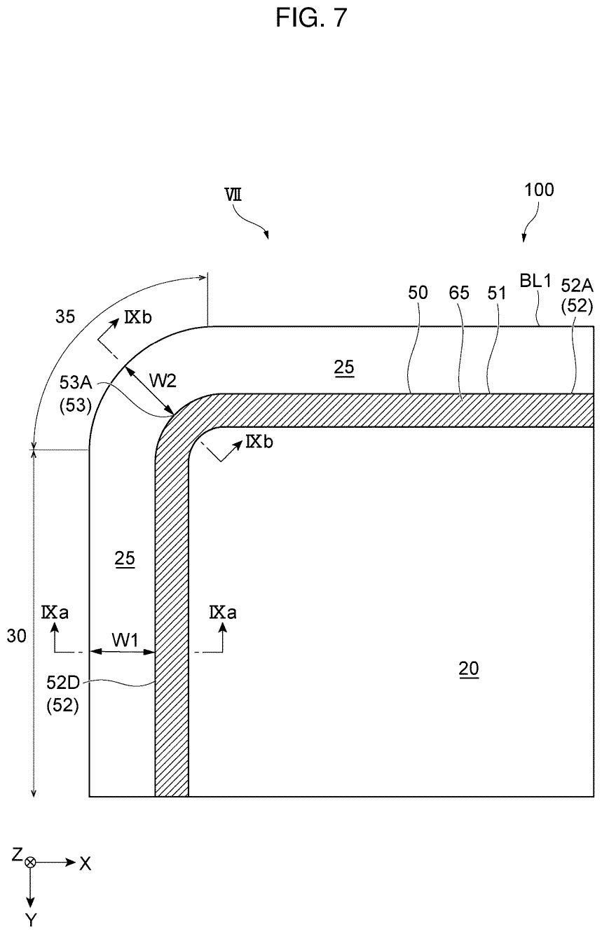

Below, the principle for improving the withstand voltage of the semiconductor device 1 will be described by comparison to a semiconductor device 100 according to a comparison example. FIG. 6 is a schematic view of a relationship between the embedded layer and the high voltage element region according to a comparison example. FIG. 7 is an enlarged view of a region VII shown in FIG. 6. As shown in FIGS. 4 to 7, the semiconductor device according to the comparison example differs from the semiconductor device 1 of Embodiment 1 by being provided with an embedded layer BL1 instead of the embedded layer BL, and the semiconductor devices are otherwise the same.

Whereas the embedded layer BL has a set-back shape at the curved section 35, the embedded layer BL1 does not have a set-back shape. The outer edge of the embedded layer BL1 protrudes from the outer edge 51 by substantially the same degree in both the curved section 35 and the extending section 30 in a plan view. That is, the width W1 is equal to the width W2 in the embedded layer BL1.

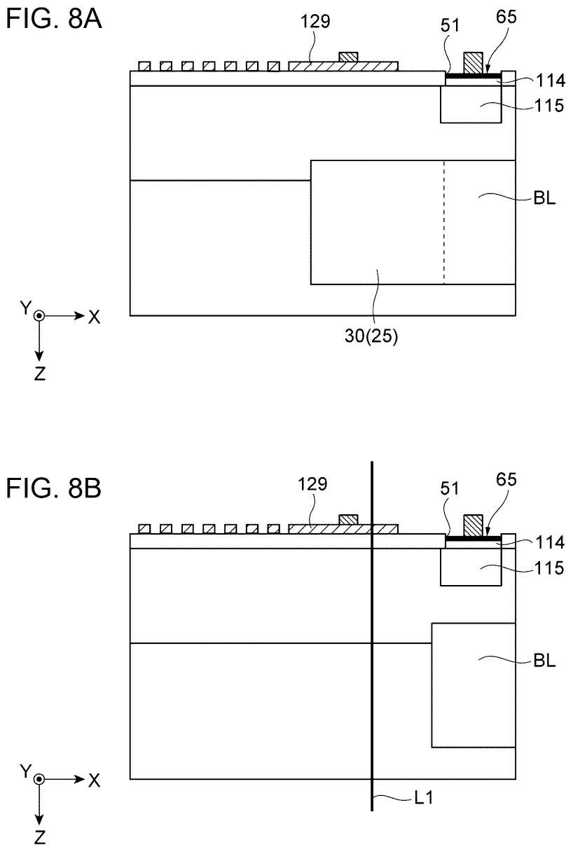

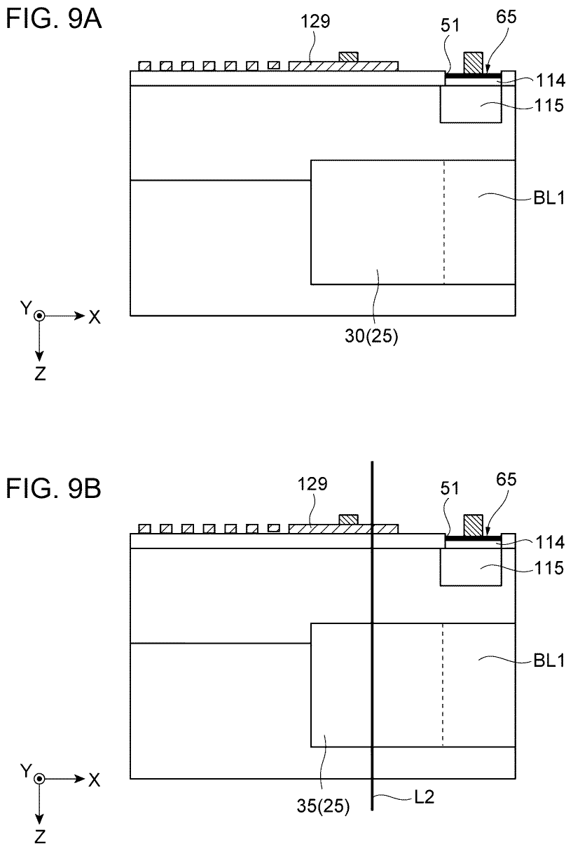

Furthermore, a comparison of cross-sectional views of the same position in FIGS. 5 and 7 will be described. FIG. 8A is a cross-sectional view along the line VIIIa-VIIIa in FIG. 5, and FIG. 8B is a cross-sectional view along the line VIIIb-VIIIb in FIG. 5. FIG. 9A is a cross-sectional view along the line IXa-IXa in FIG. 7, and FIG. 9B is a cross-sectional view along the line IXb-IXb in FIG. 7.

FIGS. 8A and 8B are both cross-sectional views indicating the positional relationship between the embedded layer BL and the active region 65 at the extending section 30 and the curved section 35 of Embodiment 1. FIGS. 9A and 9B are both cross-sectional views indicating the positional relationship between the embedded layer BL1 and the active region 65 at the extending section 30 and the curved section 35 of the comparison example. In comparing FIGS. 8A and 8B, in Embodiment 1, the position of the outer edge of the embedded layer BL in the curved section 35 is set back towards the active region 65 as compared to the outer edge of the embedded layer BL in the extending section 30. In comparing FIGS. 9A and 9B, the outer edge of the embedded layer BL1 in the curved section 35 and the outer edge of the embedded layer BL1 in the extending section 30 protrude by substantially the same degree from the outer edge 51 of the active region 65. In comparing FIGS. 8A and 9A, in the extending section 30, the embedded layer BL protrudes by the same degree as the embedded layer BL1.

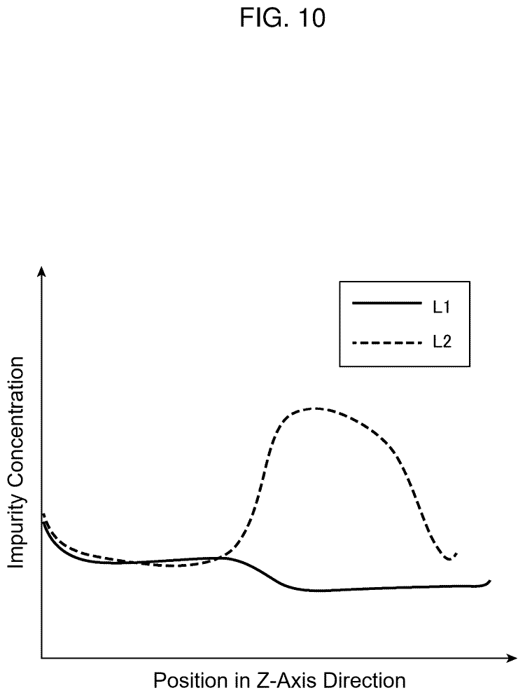

Furthermore, in FIGS. 8B and 9B, the impurity concentrations were measured along the lines L1 and L2 along the Z axis direction passing through the respective first ends 129 of the field electrodes 125. FIG. 10 is a graph comparing the impurity concentration along the line L1 of the configuration shown in FIGS. 8A and 8B, and the impurity concentration along the line L2 of the configuration shown in FIGS. 9A and 9B. As shown in FIG. 10, along the Z axis direction, the change in impurity concentration along the line L1 is gradual, whereas the change in impurity concentration along the line L2 is abrupt. This is because, in the comparison example, the embedded layer BL1, which has a high impurity concentration, is present between the semiconductor layer 13 and the semiconductor substrate 11, whereas in the working example corresponding to Embodiment 1, only the semiconductor layer 13 and the semiconductor substrate 11 are present. In particular, the electric field tends to concentrate in the vicinity of the corner 53 of the high voltage element region 50, and thus, an abrupt increase in impurity concentration poses the risk of causing a breakdown.

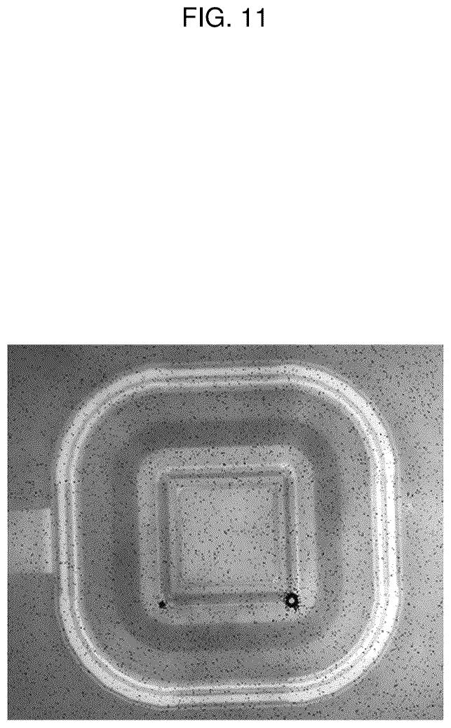

The inventor of the present invention has conducted a voltage breakdown experiment for the working example and the comparison example. FIG. 11 is a photograph showing the result of the voltage breakdown experiment. More specifically, the positions where breakdown has occurred were analyzed by luminescence analysis while applying voltage to the high voltage clement regions of the semiconductor devices of the working example and the comparison example. According to FIG. 11, it can be seen that breakdown has occurred in the vicinity of the corners of the high voltage clement region. In this experiment, a semiconductor device, in which one electrode pad is disposed on the entire section where the high voltage element inside the active region is disposed, was used.

The inventor of the present invention conducted the voltage breakdown experiment for the working example and the comparison example and measured the breakdown voltage. The breakdown voltage of the working example was 62V greater than the breakdown voltage of the comparison example. That is, in Embodiment 1, by setting the width by which the curved section 35 of the embedded layer BL protrudes beyond the outer edge 51 of the high voltage element region 50 to less than the width by which the extending section 30 of the embedded layer BL protrudes beyond the outer edge 51 of the high voltage element region 50, the concentration of electric field in the vicinity of the corners 53 of the high voltage element region 50 can be mitigated, and thus, the withstand voltage can be improved.

### Embodiment 2

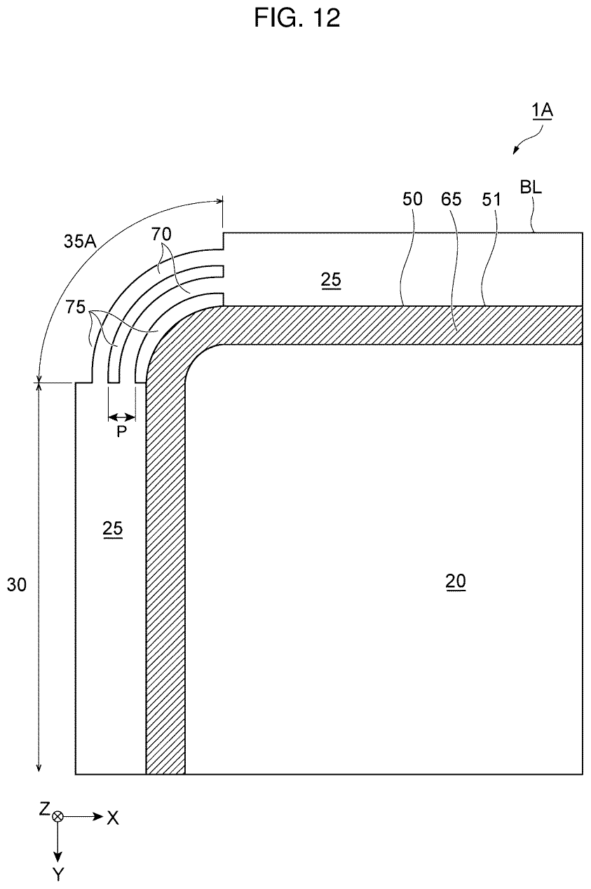

FIG. 12 is an expanded view of the configuration of a main section of a semiconductor device according to Embodiment 2. A semiconductor device 1A according to Embodiment 2 is configured such that a curved section 35A of the embedded layer BL includes first portions 70 having the same impurity concentration as that of the extending section 30, and second portions 75 having a lower impurity concentration than that of the extending section 30. In FIG. 12, the first portions 70 and the second portions 75 are arranged alternately to form a stripe pattern. As a result, it is possible to lower the average impurity concentration of the curved section 35A. Thus, the impurity concentration of the extending section 30 is greater than the impurity concentration of the curved section 35A. Therefore, the concentration of electric field in the vicinity of the corners 53 of the high voltage element region 50 can be mitigated, and thus, the withstand voltage can be improved.

The first portions 70 and the second portions 75 both have a shape tracing the outer shape of the corner 53 of the high voltage element region 50. In the example shown in the drawing, the first portions 70 and the second portions 75 both have an arc shape tracing the arc of the corner 53. The first portions 70 and the second portions 75 are arranged alternately from the inside to the outside of the curved section 35A. In the example shown in the drawing, the second portion 75 is disposed at the innermost portion of the curved section 35A, and is adjacent to the arc of the corner 53 of the high voltage element region 50. The second portion 75 is also disposed at the outermost portion of the curved section 35A. Thus, there are more second portions 75 than first portions 70. However, the order of arrangement of the first portions 70 and the second portions 75 may be interchanged, and the numbers of first portions 70 and second portions 75 may be changed. A pitch P that is the total width of one set including a first portion 70 and a second portion 75 that are adjacent to each other is 1 μm, for example.

The arrangement and shape of the first portions 70 and the second portions 75 can be adjusted as appropriate according to the pattern of the mask used when forming the embedded layer BL by ion implantation, for example.

The inventor of the present invention has also conducted a voltage breakdown experiment for the working example corresponding to the depicted example of Embodiment 2. The breakdown voltage of the working example corresponding to the depicted example of Embodiment 2 was 15V greater than the breakdown voltage of the above-mentioned comparison example.

### Embodiment 3

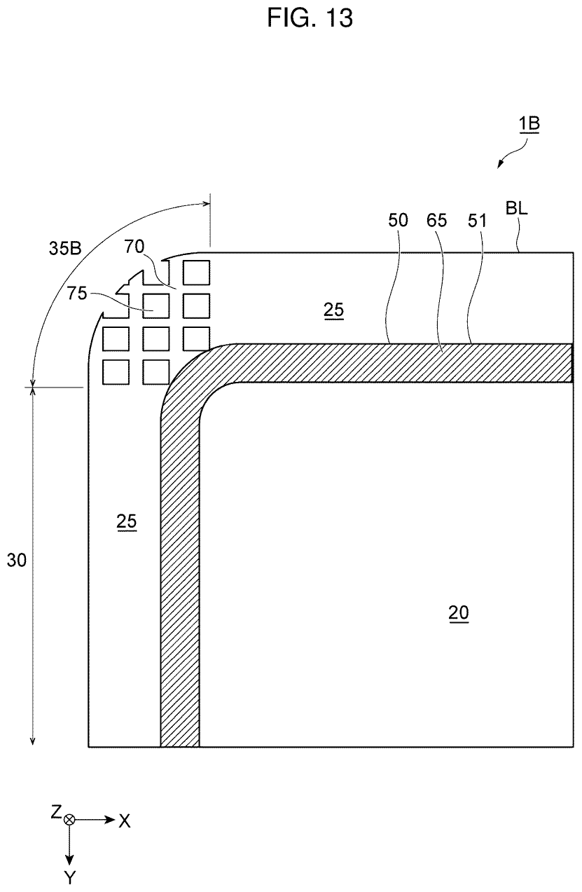

FIG. 13 is an expanded-sectional view of the configuration of a main section of a semiconductor device according to Embodiment 3. A semiconductor device 1B according to Embodiment 3 is configured such that a curved section 35B of the embedded layer BL includes first portions 70 having the same impurity concentration as that of the extending section 30, and second portions 75 having a lower impurity concentration than that of the extending section 30. In FIG. 13, the first portions 70 and the second portions 75 are arranged alternately to form a matrix pattern. As a result, the electric field in the vicinity of the corners of the high voltage clement region 50 can be suppressed, and thus, the withstand voltage can be improved.

According to the embodiments described above, it is possible to provide a semiconductor device by which the withstand voltage can be improved.

In the embodiments described above, one or more elements of a given embodiment may be combined with one or more elements of another embodiment.

Below, characteristic examples derived from the specification and the drawings are disclosed.

[A1] A semiconductor device (1), including:
a semiconductor substrate (11);
a semiconductor layer (13) provided on the semiconductor substrate;
a high voltage element region (50) and a low voltage element region (55) provided to the semiconductor layer;
an isolation structure (15) that is formed on an insulating film (60) formed on a surface (3) of the semiconductor layer, and that surrounds a periphery of the high voltage element region (50) so as to isolate the high voltage element region from the low voltage element region (55); and
an embedded layer (BL) interposed between the semiconductor substrate and the semiconductor layer,
wherein, in a plan view,
   the high voltage element region (50) includes outer edges (51) having linear sides (52A-52D) and corners (53A-53D),
   the embedded layer (BL) has an overlap section (20) where the embedded layer overlaps the high voltage element region, and outer edge sections (25) that protrude from the outer edges,
   the outer edge sections include extending sections (30) corresponding to the sides and curved sections (35) corresponding to the corners, and
   a width (W1) of each of the extending sections is greater than a width (W2) of each of the curved sections.

[A2] The semiconductor device according to [A1],
wherein the surface of the semiconductor layer includes a loop-shaped active region (65) exposed through the insulating film (60), and
wherein the outer edges are constituted of outer edges of the active region.

[A3] The semiconductor device according to [A2],
wherein, in a plan view,
   the high voltage element region has a rectangular shape, and
   the active region has a rectangular loop shape corresponding to the shape of the high voltage element region.

[A4] The semiconductor device according to any one of [A1] to [A3].
wherein, in a plan view, a curvature radius of the curved section is greater than a curvature radius of the corner.

[A5] The semiconductor device according to [A4],
wherein, in a plan view, a vertex of the curved section overlaps a vertex of the corner.

[A6] A semiconductor device, including:
a semiconductor substrate;
a semiconductor layer provided on the semiconductor substrate;
a high voltage element region and a low voltage element region provided to the semiconductor layer;
an isolation structure that is formed on an insulating film formed on a surface of the semiconductor layer, and that surrounds a periphery of the high voltage element region so as to isolate the high voltage element region from the low voltage element region; and
an embedded layer interposed between the semiconductor substrate and the semiconductor layer,
wherein, in a plan view,
   the high voltage element region includes outer edges having linear sides and corners,
   the embedded layer has an overlap section where the embedded layer overlaps the high voltage element region, and outer edge sections that protrude from the outer edges, and
   the outer edge sections include extending sections corresponding to the sides and curved sections corresponding to the corners, and
wherein an impurity concentration of each of the extending sections is greater than an impurity concentration of each of the curved sections.

[A7] The semiconductor device according to [A6],
wherein the surface of the semiconductor layer includes a loop-shaped active region exposed through the insulating film, and
wherein the outer edges are constituted of outer edges of the active region.

[A8] The semiconductor device according to [A7],
wherein, in a plan view,
   the high voltage element region has a rectangular shape, and
   the active region has a rectangular loop shape corresponding to the shape of the high voltage element region.

[A9] The semiconductor device according to any one of [A6] to [A8].
wherein the curved section includes a first portion (70) having a same impurity concentration as the impurity concentration of each of the extending sections, and a second portion (75) having a lower impurity concentration than the impurity concentration of each of the extending sections.

[A10] The semiconductor device according to [A9],
wherein the first portion and the second portion are arranged alternately to form a stripe pattern.

[A11] The semiconductor device according to [A9],
wherein the first portion and the second portion are arranged alternately to form a matrix pattern.

What is claimed is:

1. A semiconductor device, comprising:
a semiconductor substrate;
a semiconductor layer provided on the semiconductor substrate;
a high voltage element region and a low voltage element region provided to the semiconductor layer;
an isolation structure that is formed on an insulating film formed on a surface of the semiconductor layer, and that surrounds a periphery of the high voltage element region so as to isolate the high voltage element region from the low voltage element region; and
an embedded layer interposed between the semiconductor substrate and the semiconductor layer,
wherein, in a plan view,
the high voltage element region includes outer edges having linear sides and corners,
the embedded layer has an overlap section where the embedded layer overlaps the high voltage element region, and outer edge sections that protrude from the outer edges,
the outer edge sections include extending sections corresponding to the sides and curved sections corresponding to the corners, and
a width of each of the extending sections is greater than a width of each of the curved sections.

2. The semiconductor device according to claim 1,
wherein the surface of the semiconductor layer includes a loop-shaped active region exposed through the insulating film, and
wherein the outer edges are constituted of outer edges of the active region.

3. The semiconductor device according to claim 2,
wherein, in a plan view,
the high voltage element region has a rectangular shape, and
the active region has a rectangular loop shape corresponding to the shape of the high voltage element region.

4. The semiconductor device according to claim 1,
wherein, in a plan view, a curvature radius of the curved sections is greater than a curvature radius of the corners.

5. The semiconductor device according to claim 4,
wherein, in a plan view, a vertex of the curved sections overlaps a vertex of the corners.

6. A semiconductor device, comprising:
a semiconductor substrate;
a semiconductor layer provided on the semiconductor substrate;
a high voltage element region and a low voltage element region provided to the semiconductor layer;
an isolation structure that is formed on an insulating film formed on a surface of the semiconductor layer, and that surrounds a periphery of the high voltage element region so as to isolate the high voltage element region from the low voltage element region; and
an embedded layer interposed between the semiconductor substrate and the semiconductor layer,
wherein, in a plan view,
the high voltage element region includes outer edges having linear sides and corners,
the embedded layer has an overlap section where the embedded layer overlaps the high voltage element region, and outer edge sections that protrude from the outer edges, and
the outer edge sections include extending sections corresponding to the sides and curved sections corresponding to the corners, and
wherein an impurity concentration of each of the extending sections is greater than an impurity concentration of each of the curved sections.

7. The semiconductor device according to claim 6,
wherein the surface of the semiconductor layer includes a loop-shaped active region exposed through the insulating film, and
wherein the outer edges are constituted of outer edges of the active region.

8. The semiconductor device according to claim 7,
wherein, in a plan view,
the high voltage element region has a rectangular shape, and
the active region has a rectangular loop shape corresponding to the shape of the high voltage element region.

9. The semiconductor device according to claim 6,
wherein the curved sections include a first portion having a same impurity concentration as the impurity concentration of each of the extending sections, and a second portion having a lower impurity concentration than the impurity concentration of each of the extending sections.

10. The semiconductor device according to claim 9,
wherein the first portion and the second portion are arranged alternately to form a stripe pattern.

11. The semiconductor device according to claim 9,
wherein the first portion and the second portion are arranged alternately to form a matrix pattern.
